(19) United States
(12) Patent Application Publication
(10) Pub. No.: US 2026/0031777 A1
(43) Pub. Date: Jan. 29, 2026

(54) LINK RECEIVER CIRCUITRY FOR CONTROLLER-MEMORY DEVICE INTERFACES IN DATA STORAGE DEVICES

(71) Applicant: Sandisk Technologies, Inc., Milpitas, CA (US)

(72) Inventors: ASHISH SAVADIA, Bengaluru (IN); RAMAKRISHNAN SUBRAMANIAN, Bengaluru (IN); SHIV HARIT MATHUR, Bengaluru (IN)

(73) Assignee: Sandisk Technologies, Inc., Milpitas, CA (US)

(21) Appl. No.: 18/780,696

(22) Filed: Jul. 23, 2024

(51) Int. Cl. H03F 3/45

(52) U.S. Cl. CPC H03F 3/45179; H03F 2203/45394

(57) ABSTRACT

A receiver circuitry in a storage device may operate in stages. An amplifier in a first stage may receive an input and produce a high gain for all speeds with gain booster cells and a complementary input folded cascade structure. An equalizer including a resistor and a capacitor may increase the gain at high speeds in a second stage. In a third stage, a level down shifter may correct a duty cycle error resulting from shifting a signal across domain. The receiver circuitry may thus be used in different categories of storage devices with varying requirements.

### BACKGROUND OF THE INVENTION

A storage device may be communicatively coupled to a host and to non-volatile memory including, for example, a NAND flash memory device on which the storage device may store data received from the host. Memory devices may store information on dies and the memory devices may be configured to support different die loads and speeds. Storage devices may be grouped in different categories, wherein storage devices in each category may have different requirements to support a given speed range, power level, die load, etc. Storage devices in each category may have different types of challenges posed, for example, by packaging cross-talks which may occur in a 2-layer package, power delivery networks, long data channel (for example, approximately 3 inch or 80 millimeters (mm)), high die loading (for example, 10 picofarad (pF)-32 pF), etc.

Categories of storage devices may include, for example, client storage devices, enterprise storage devices, role-playing game (RPG) storage devices, iNAND storage devices, etc. Client storage devices may support relatively higher data rates of approximately 2400 megabits per second (mbps) and may support a relatively lower capacity requirement of, for example, four dies. The channel lengths in client storage devices may be greater than eight mm, in some configurations, which may cause high channel loss and crosstalk. Enterprise storage devices may support higher memory capacities of, for example, eight-sixteen dies at lower speeds of, for example, approximately 1200 mbps, with a greater number of channels to saturate the host. The large number of data channels in enterprise storage devices, for example, up to sixteen bytes, may increase supply noise, impacting the system margins and power. Low input slew rates in enterprise storage devices (for example, 0.4 volts (V) per nanosecond (ns)) may impact the read margins due to heavily loaded lines. The speed requirements of RPG storage devices may be higher than that of enterprise storage devices and lower than the speed requirements of client storage devices. RPG storage devices may be more power sensitive than other types of storage devices and may have a maximum 2-layer package which may degrade the signal and power integrity (due to internal regulators) of the data while supporting the die load and data rates.

To reduce costs associated with developing and testing different categories of storage devices to satisfy the varying requirements including, power, performance, and area, of different categories of storage devices, a single storage device architecture that may accommodate the varying requirements of the different categories may be desirable. Such an architecture may be designed to be reused across different storage device categories.

A current storage device design includes an all-thick oxide based single stage complementary input receiver where an input analog signal from the memory device may be digitized and level down shifted to a core domain for further processing inside the storage device. One challenge with this design is that the architecture is a low bandwidth design which may include two pseudo differential amplifiers connected in parallel, increasing the load inside the receiver. This architecture may not be scaled for the high speeds used, for example, in client storage devices, because as more speed is introduced in the receiver, more loads may be produced on the output lines of the receiver. As such, the receiver performance in this design may degrade if speeds are stretched up to 2400 mbps, a requirement in client storage devices. Moreover, due to a self-bias approach in this architecture, higher speeds may produce higher supply noise.

Furthermore, due to use of thick oxide devices in a level down shifter and the lower bandwidth, the overall penalty of the receiver may increase to approximately 80 peco-seconds (ps) at 1200 mbps. In this architecture it may also be difficult to implement a Continuous Time Linear Equalizer (CTLE) due to the low bandwidth of a first stage required to amplify high frequency signal that face maximum attenuation. Hence this architecture is not scalable to meet the varying requirements of different categories of storage devices including, for example, the high data speed requirements of some storage devices.

### SUMMARY OF THE INVENTION

In some implementations, a receiver circuitry in a storage device may provide an interface between a controller and a memory device in the storage device, the receiver circuitry may include an amplifier to receive an input and produce a high gain at high and low speeds. An equalizer in the circuitry may increase the gain at high speeds. A skew balanced level down shifter may correct a duty cycle error resulting from shifting a signal across domain.

In some implementations, the receiver circuitry in a storage device may operate in stages, wherein an amplifier in a first stage may receive an input and produce a high gain with a complementary input folded cascade structure. An equalizer including a resistor and a capacitor may increase the gain at high speeds in a second stage. In a third stage, a level down shifter may correct a duty cycle error resulting from shifting a signal across domain.

In some implementations, a method for interfacing between a controller and a memory device in the storage device with a receiver circuitry in the storage device, includes receiving an input and producing a high gain with gain booster cells and a complementary input folded cascade structure in a first stage. The method also includes increasing the gain at high speeds with an equalizer in a second stage. The method further includes correcting a duty cycle error resulting from shifting a signal across domain with a level down shifter in a third stage.

### BRIEF DESCRIPTION OF THE DRAWINGS

FIG. 1 is a schematic block diagram of an example system in accordance with some implementations.

FIG. 2 is a schematic diagram of a current single stage complementary input receiver 106 used in a storage device.

FIG. 3 is another schematic diagram of the single stage complementary input receiver with a continuous time linear equalizer.

FIG. 4 is schematic diagram of an exemplary complementary input receiver used in a storage device in accordance with some embodiments.

FIG. 5 shows a simulation of gain at high and low frequencies using the receiver of FIG. 4 in accordance with some implementations.

FIGS. 6A-6D show a simulation of a storage device in one category using a receiver of FIG. 3 and a receiver of FIG. 4 in accordance with some implementations.

FIG. 7 is an example flow diagram for processing data in a receiver on a storage device in accordance with some implementations.

FIG. 8 is a diagram of an example environment in which systems and/or methods described herein are implemented.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of implementations of the present disclosure.

The apparatus and method components have been represented where appropriate by conventional symbols in the drawings, showing those specific details that are pertinent to understanding the implementations of the present disclosure so as not to obscure the disclosure with details that will be readily apparent to those of ordinary skill in the art.

### DETAILED DESCRIPTION OF THE INVENTION

The following detailed description of example implementations refers to the accompanying drawings. The same reference numbers in different drawings may identify the same or similar elements.

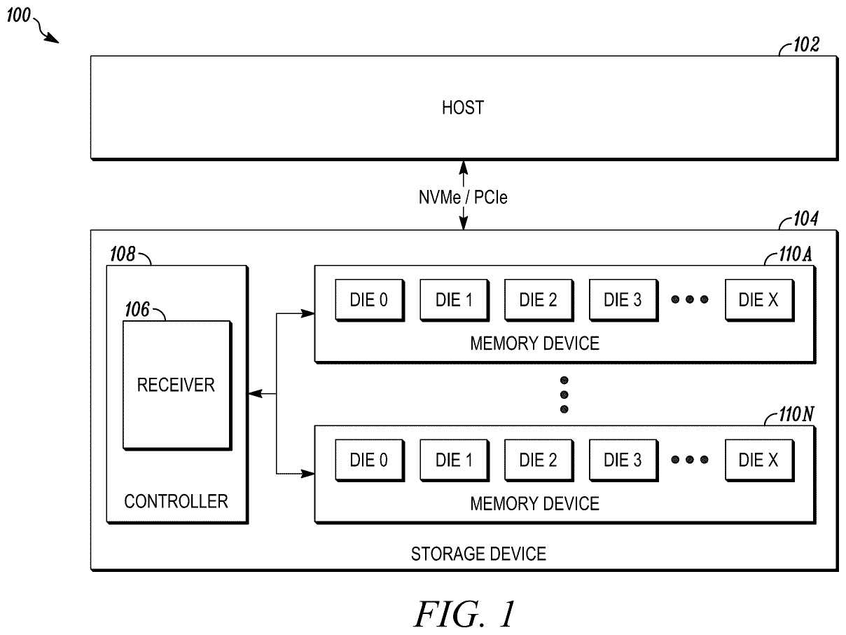

FIG. 1 is a schematic block diagram of an example system in accordance with some implementations. System 100 includes a host 102 and a storage device 104 that may be in the same physical location as components on a single computing device or on different computing devices that are communicatively coupled. Storage device 104, in various embodiments, may be disposed in one or more different locations relative to the host 102. System 100 may include additional components (not shown in this figure for the sake of simplicity).

Storage device 104 may include a receiver 106, a controller 108 and one or more non-volatile memory devices 110a-110n (referred to herein as the memory device(s) 110). Storage device 104 may be, for example, a solid-state drive (SSD). Receiver 106 may be designed to accommodate the varying requirements including speeds, die loads, and power sensitivity, across the different categories of storage devices. Controller 108 may manage the resources on the storage device to optimize how space on memory device 110 is used and improve efficiency.

Memory device 110 may be flash based. For example, memory device 110 may be a NAND or NOR flash memory that may be used for storing host and control data over the operational life of memory device 110. Memory device 110 may include multiple dies for storing the data. Data may be stored in blocks on the dies in various formats, with the formats being defined by the number of bits that may be stored per memory cell. Memory device 110 may be included in storage device 104 or may be otherwise communicatively coupled to storage device 104. As indicated above FIG. 1 is provided as an example. Other examples may differ from what is described in FIG. 1.

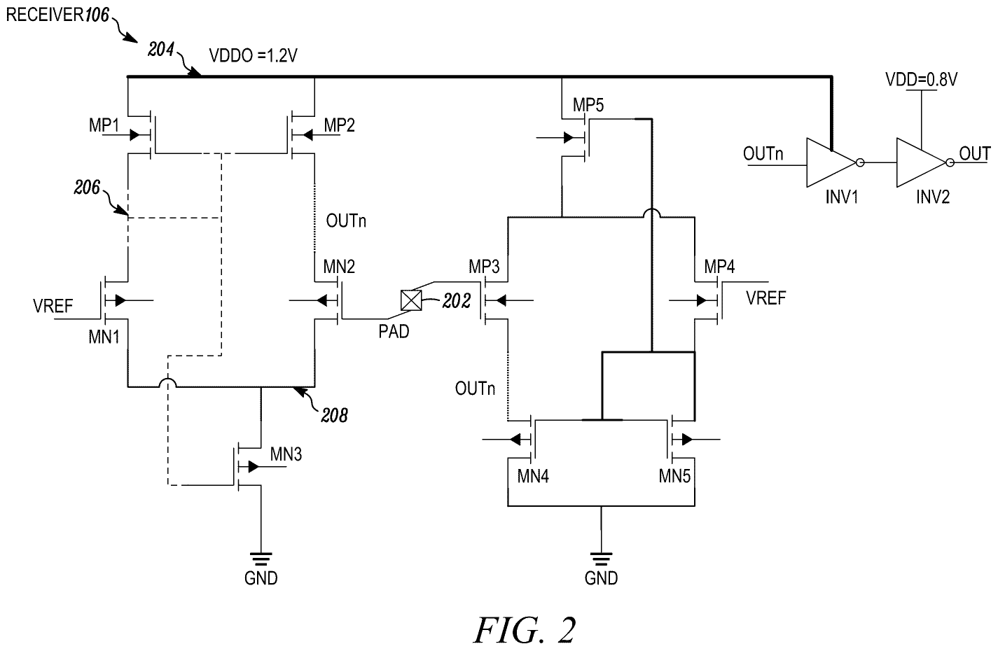

FIG. 2 is a schematic diagram of a current single stage complementary input receiver used in a storage device. Receiver 106 may be an all-thick oxide based single stage complementary input receiver where an analog input data signal (PAD 202) received from memory device 110 may be compared with a static configurable reference voltage (Vref). The input analog signal from memory device 110 may be in a 1.2/1.8-volt (V) domain and may be digitized and level down shifted to a core domain (for example, 0.8V) for further processing inside a flash interface module (FIM) (not shown) in storage device 104.

The design of receiver 106 may be interpreted as two pseudo differential amplifiers, one PMOS based and one NMOS based, connected in parallel to increase an overall gain, wherein the outputs from both amplifiers may be combined and digitized. By increasing the gain, the design of receiver 106 may reduce the bandwidth and increase the load of receiver 106. Receiver 106 may thus fail at higher speeds, including, for example, speeds of approximately 2400 mbps used in client storage devices.

Due to use of thick oxide devices in a level down shifter and the lower bandwidth of receiver 106, the overall penalty (for example, jitter, duty cycle error) of receiver 106 may increase to approximately 80 ps at 1200 mbps. Moreover, when there is noise on supply 204 (i.e., 1.2 V), it goes directly into wire 206 which may be shorted to tail gate MN3. The noise in gate MN3 may get amplified and modulate wire 208 and ultimately OUTn. Hence, the receiver penalty is not immune to supply noise due to the self-bias approach in the design of receiver 106 where the mirror net is connected to gate of tail devices. As such, the power supply rejection ratio (PSRR) may be very poor as the supply noise may now directly modulate the tail devices and get amplified at the OUTn net.

In designing receiver 106 to meet the high data speed requirements of, for example, client storage devices, a Continuous Time Linear Equalizer (CTLE) may be needed. In receiver 106 as shown in FIG. 2, it may be difficult to implement the CTLE due to the low bandwidth required to amplify high frequency signals that face maximum attenuation. Hence, the design used for receiver 106 may not be scalable to meet the high data speed requirements of some categories of storage devices. As indicated above FIG. 2 is provided as an example. Other examples may differ from what is described in FIG. 2.

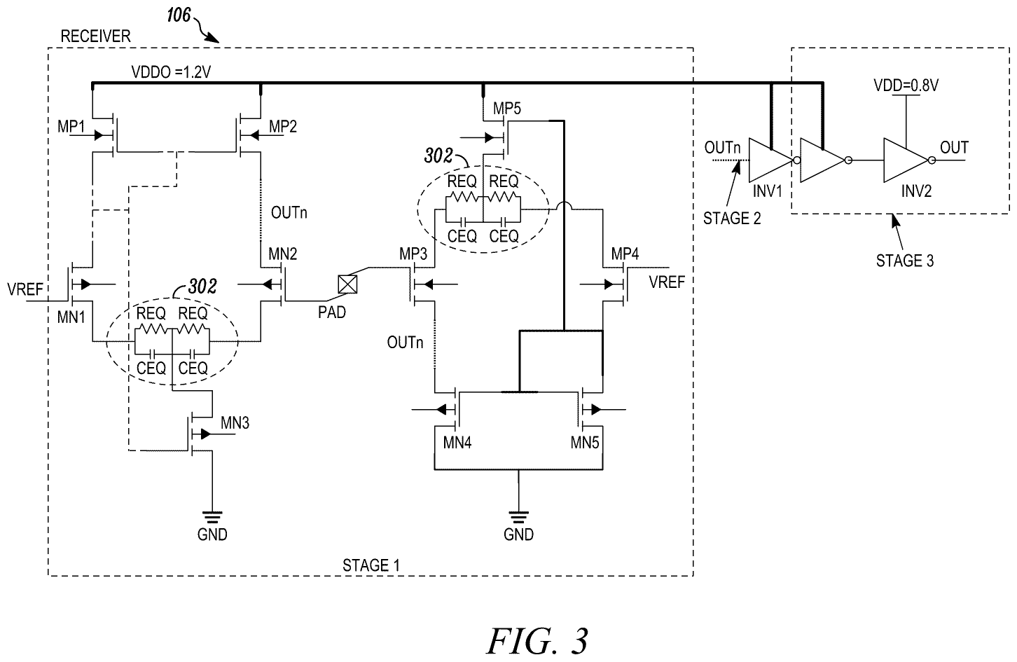

FIG. 3 is another schematic diagram of the single stage complementary input receiver with a continuous time linear equalizer. FIG. 3 shows a modified receiver 106, wherein receiver 106, as shown in FIG. 2, has been modified to include four resisters and four capacitors to provide an equalizer 302. Thus, modified receiver 106, shown in FIG. 3, includes eight more components than is shown in FIG. 2, to provide additional gain at higher data rates. Due to the additional components, implementing equalizer 302 in receiver 106 may be challenging as equalizer 302 may consume a relatively large area and more power. Furthermore, at the cost of increasing the high frequency gain in receiver 106, equalizer 302 may reduce the low frequency gain of receiver 106. This may be an issue when working at relatively lower speed but at a higher capacity using, for example, an enterprise storage device.

The functions of receiver 106 may be divided in three stages, wherein stage 1 may be a low gain stage due to equalizer 302. Stage 2 may be a high input impedance gain stage, wherein there may be heavy loading on the output (OUTn) due the large size on the invertor (INV 1) and the high impedance of MP2 and MN4 (i.e., devices that provide adequate impedance to define the gain in the amplifier, wherein the higher the impedance the more the gain). Stage 3 may be a level down shifting stage wherein there may be heavy duty cycle loss due to the direct level shift from 1.2V to 0.8V using thick oxide devices. As indicated above FIG. 3 is provided as an example. Other examples may differ from what is described in FIG. 3.

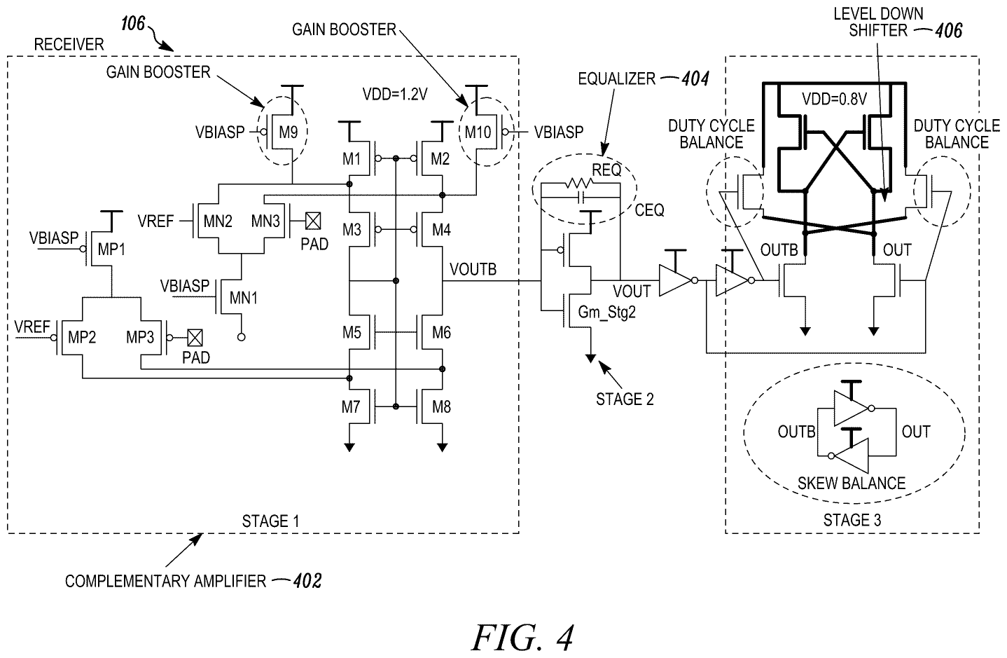

FIG. 4 is schematic diagram of an exemplary complementary input receiver used in a storage device in accordance with some embodiments. Receiver 106 includes a complementary amplifier 402, an equalizer 404, and a skew balanced level down shifter 406. Complementary amplifier 402 may receive an input of about 200 milli-Volts (mV) and produce a high gain in a first stage such that complementary amplifier 402 may boost the gain at all speeds, including at low frequencies. In this architecture, instead of implementing an equalizer in the Stage 1, as shown in FIG. 3 wherein four resistors and four capacitors are used in stage 1 to implement equalizer 302, the receiver design in FIG. 4 obtains high gain with a complementary input folded cascade structure (MN2, MN3, MP2, MP3). Complementary inputs into amplifier 402 may provide a high input common mode range of, for example, 0.4*VDDO to 0.6*VDDO, a requirement for some storage devices that require unterminated line for power saving (wherein VDDO is the interface supply level (either 1.2V or 1.8V) based on the generation of NAND flash used). Due to weaker PMOS devices as compared to NMOS, gain boosters cells (M9, M10) in addition to devices M1 and M3, M2 and M4, M5 and M7, and M6 and M8 may provide additional gain and large output swing with better operating range, wherein:

$$DC gain = 2 ( {g}_{mp 2 / 3} + {g}_{mn 2 / 3} ) ( {ro}_{m 9} {g}_{m 4} {ro}_{m 4} ‖ {ro}_{m 8} {g}_{m 6} {ro}_{m 6} ) ‖ {R}_{e q} ,$$

wherein g_{mp2/3} and g_{mn2/3} is the transconductance of devices MP2, MP3, MN2, MN3 of FIG. 4, when input pad voltage=0.5*VDDO (or 0.6V if the VDDO=1.2V),
gₘ₄ and gₘ₆ is the transconductance of devices M4, M6 of FIG. 4 when the input pad voltage=0.5*VDDO=0.6V (if the VDDO=1.2V),
roₘ₉, roₘ₄, roₘ₆, roₘ₈ is the output impedance of devices M9, M4, M6, M8 of FIG. 4 respectively when the input pad voltage=0.5*VDDO=0.6V (if the VDDO=1.2V), and
R_{eq} is the tunable resistor in the 2nd stage for implementing the equalizer

Equalizer 404 may be used in a second stage to increase the gain at high speeds. Equalizer action may be achieved at high frequency (for example, approximately 1.4 GHz) by designing a low impedance stage 2 using only one resistor and one capacitor. The peak frequency (CTLE action) may be tunable through the capacitor (Ceq) and provided by the following equation 2:

$${ω}_{z} = \frac{1}{{C}_{e q}} * ( {G}_{m \_ stage 2} - \frac{1}{{R}_{eq}} )$$

wherein, G_{m_stage2} is equal to the total transconductance of stage 2 (Gm_m11+Gm_m12), C_{eq} is a tunable capacitor, and R_{eq} is a tunable resistor.

Stage 2 provides a low impedance path through the resistor (R_{eq}) to improve the bandwidth of Stage 1 thereby pushing the pole further to the right as shown in equation:

$${ω}_{pout} = \frac{1}{{C}_{e q} ( {ro}_{m 2} {g}_{m 4} r {o}_{m 4} ‖ {ro}_{m 8} {g}_{m 6} {ro}_{m 6} ) ‖ {R}_{e q}}$$

wherein roₘ₂ is the output impedance of device M2 of FIG. 4 when the input pad voltage=0.5*VDDO=0.6V (if the VDDO=1.2V)

A design ensuring Wz<0.6*Wpout, may give good equalization of ˜7 dB, where Wz and Wpout is the angular frequency as derived from the above equation 2. where Wz is the zero frequency as seen at node VOUT (output of Stage 2) and Wpout is the pole frequency observed at node VOUT (output of Stage 2).

Instead of directly transferring the data to the core voltage (for example, 0.8V) so that the core circuitry of storage device 104 may process the data further, as is shown in FIGS. 2 and 3, skew balanced level shifter 406 may correct the duty cycle error that may occur from shifting the signal across domain from, for example, 1.2 V to the core voltage of 0.8 V. Two signals, one is an inverted signal of the other, with some delay between the signals may be inputted to skew balanced level down shifter 406. Skew balanced level shifter 406 may balance the skew, negate the impact of the skew, and level down shift the signal to the core voltage. As such, the receiver penalty and duty cycle delay may be further improved by using a dedicated differential level down shifter with a skew balancer and duty cycle balancers instead of thick oxide inverter of prior approaches shown in FIGS. 2 and 3.

The receiver architecture of FIG. 4 addresses the gain issues that occurred in stage 1 of FIG. 3 for high-capacity storage devices. The receiver architecture of FIG. 4 may also be scaled for high-speed storage devices with low capacity. The receiver architecture of FIG. 4 may occupy a low area, wherein instead of eight components (four resistors and four capacitors shown in FIG. 3), the receiver architecture of FIG. 4 uses only two components (one resistor and one capacitor) to achieve high frequency equalization within, for example, a 30 um*60 um area. As indicated above FIG. 4 is provided as an example. Other examples may differ from what is described in FIG. 4

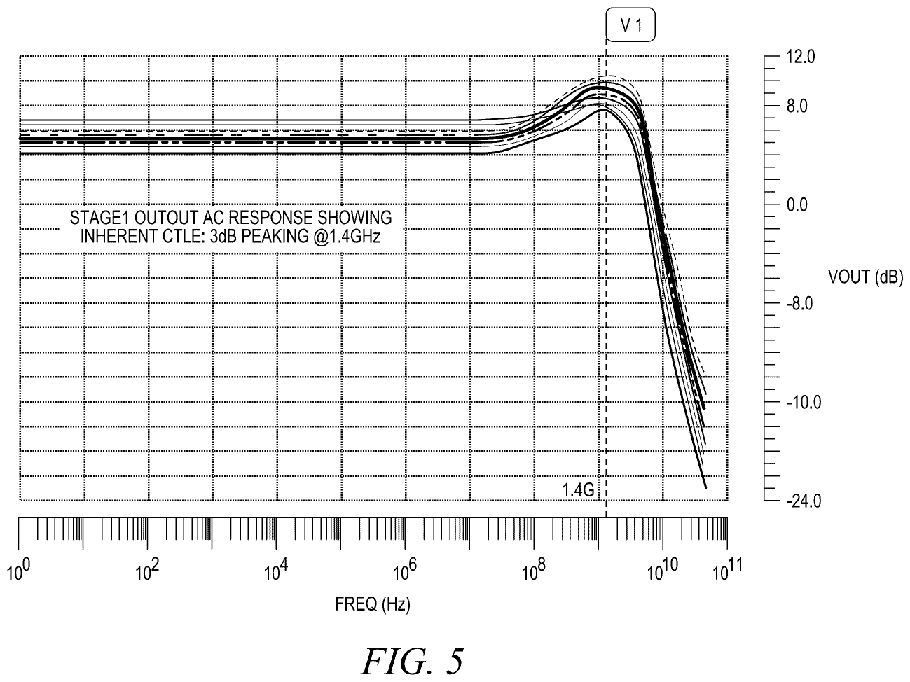

FIG. 5 shows a simulation of gain at high and low frequencies using the receiver of FIG. 4 in accordance with some implementations. As shown, the low frequencies may have some gain of approximately 3 db. As the frequency increases to 2800 mbps or 1.4 GHz, a gain of approximately 6 dB may be achieved in the worst case across all process, voltage, and temperature ranges, providing channel loss equalization at high data rates. As indicated above FIG. 5 is provided as an example. Other examples may differ from what is described in FIG. 5.

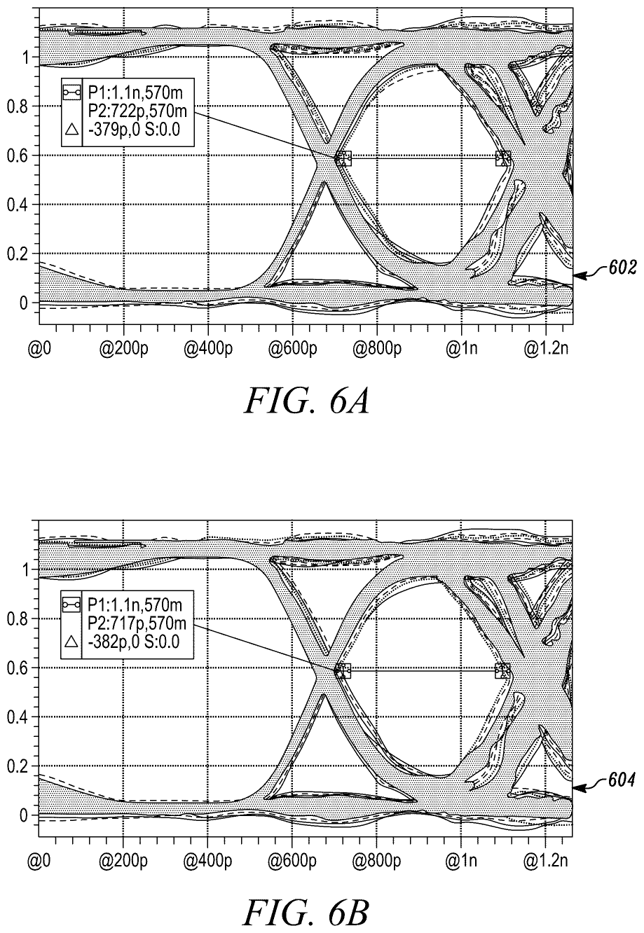

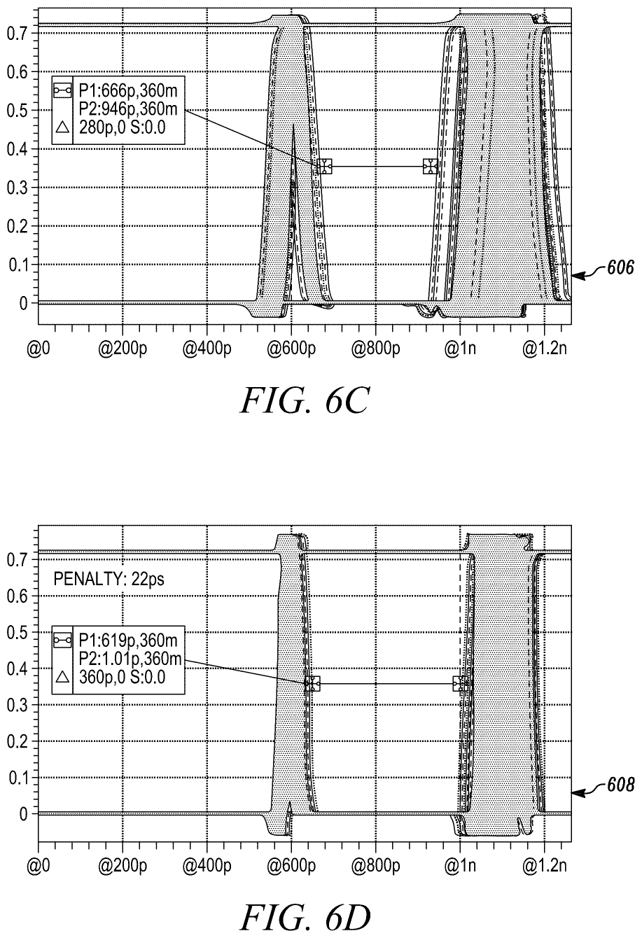

FIGS. 6A and 6C show a simulation of a storage device in one category using a receiver of FIG. 3 and FIGS. 6B and 6D show a simulation of a storage device in one category using a receiver of FIG. 4 in accordance with some implementations. The simulation shows a data rate of 1400 mbps. 602 shows the input into storage device 104 using a receiver of FIGS. 3 and 606 shows the output from the receiver of FIG. 3. 604 shows the input into storage device 104 using a receiver of FIGS. 4 and 608 shows the output from the receiver of FIG. 4. As shown in 602, the input into storage device 104 using a receiver of FIG. 3 is 379 Pico seconds (p). The output from the receiver of FIG. 3, as shown in 606, is 280 p, a difference of approximately 99 p, i.e., almost a loss of about 100 p based on the design.

The input into storage device 104 using the receiver of FIG. 4 is 382 p, as shown in 604. The output from the receiver of FIG. 4 is 360 p, as shown in 608, a difference of 22 p. As such, there may be about 78 p savings using the receiver of FIG. 4 instead of the receiver of FIG. 3. As indicated above FIGS. 6A-6D are provided as examples. Other examples may differ from what is described in 6A-6D.

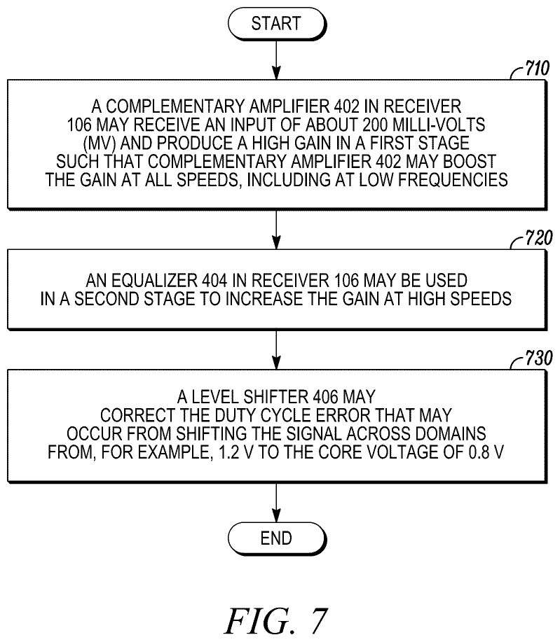

FIG. 7 is an example flow diagram for processing data in a receiver on a storage device in accordance with some implementations. At 710, a complementary amplifier 402 in receiver 106 may receive an input of about 200 milli-Volts (mV) and produce a high gain in a first stage such that complementary amplifier 402 may boost the gain at all speeds, including at low frequencies. At 720, an equalizer 404 in receiver 106 may be used in a second stage to increase the gain at high speeds. At 730, a level shifter 406 may correct the duty cycle error that may occur from shifting the signal across domains from, for example, 1.2 V to the core voltage of 0.8 V. As indicated above FIG. 7 is provided as an example. Other examples may differ from what is described in FIG. 7.

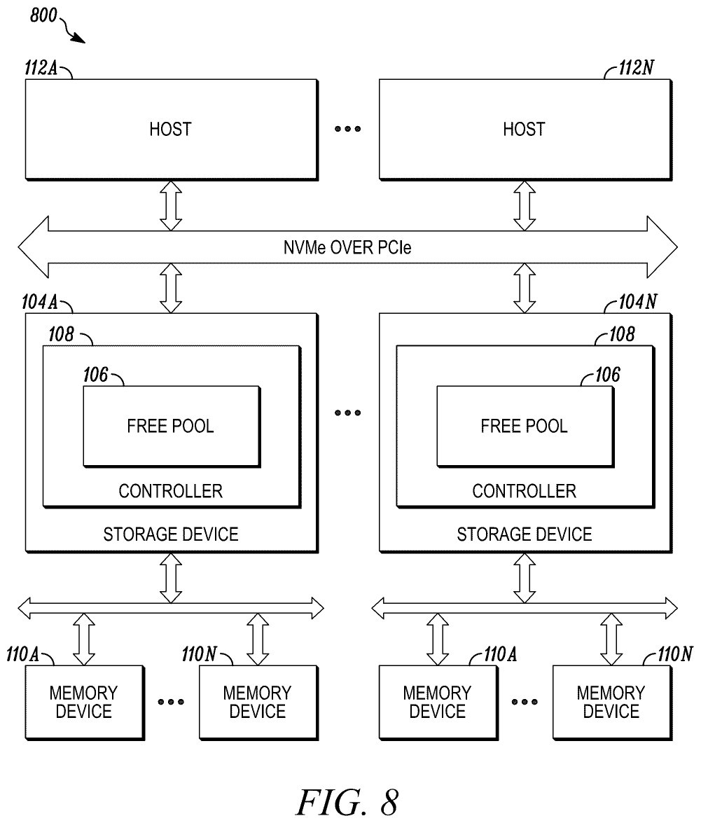

FIG. 8 is a diagram of an example environment in which systems and/or methods described herein are implemented. As shown in FIG. 8, Environment 800 may include hosts 102-102n (referred to herein as host(s) 102), and one or more storage devices 104a-104n (referred to herein as storage device(s) 104). Storage device 104 may include a controller 108 with a receiver 106 designed to operate in different categories of storage devices. Hosts 102 and storage devices 104 may communicate via Non-Volatile Memory Express (NVMe) over peripheral component interconnect express (PCI Express or PCIe), SD, or the like.

Devices of Environment 800 may interconnect via wired connections, wireless connections, or a combination of wired and wireless connections. For example, the network in FIG. 8 may include NVMe over Fabric (NVMe-oF) Internet Small Computer Systems Interface (iSCSI), Fibre Channel (FC), Fibre Channel Over Ethernet (FCOE) connectivity and any another type of next-generation network and storage protocols, a local area network (LAN), a wide area network (WAN), a metropolitan area network (MAN), a private network, an ad hoc network, an intranet, the Internet, a fiber optic-based network, a cloud computing network, or the like, and/or a combination of these or other types of networks.

The number and arrangement of devices and networks shown in FIG. 8 are provided as an example. In practice, there may be additional devices and/or networks, fewer devices and/or networks, different devices and/or networks, or differently arranged devices and/or networks than those shown in FIG. 8. Furthermore, two or more devices shown in FIG. 8 may be implemented within a single device, or a single device shown in FIG. 8 may be implemented as multiple, distributed devices. Additionally, or alternatively, a set of devices (e.g., one or more devices) of Environment 800 may perform one or more functions described as being performed by another set of devices of Environment 800.

The foregoing disclosure provides illustrative and descriptive implementations but is not intended to be exhaustive or to limit the implementations to the precise form disclosed herein. One of ordinary skill in the art will appreciate that various modifications and changes can be made without departing from the scope of the present disclosure as set forth in the claims below. Accordingly, the specification and figures are to be regarded in an illustrative rather than a restrictive sense, and all such modifications are intended to be included within the scope of present teachings.

As used herein, the term “component” is intended to be broadly construed as hardware, firmware, and/or a combination of hardware and software. It will be apparent that systems and/or methods described herein may be implemented in different forms of hardware, firmware, and/or a combination of hardware and software.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set.

No element, act, or instruction used herein should be construed as critical or essential unless explicitly described as such. Also, as used herein, the articles “a” and “an” are intended to include one or more items and may be used interchangeably with “one or more.” Furthermore, as used herein, the term “set” is intended to include one or more items (e.g., related items, unrelated items, a combination of related items, unrelated items, and/or the like), and may be used interchangeably with “one or more” The term “only one” or similar language is used where only one item is intended. Further, the phrase “based on” is intended to mean “based, at least in part, on” unless explicitly stated otherwise

Moreover, in this document, relational terms such as first and second, top and bottom, and the like, may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, or “contains . . . a” does not, without more constraints, preclude the existence of additional identical elements in the process, method, article, or apparatus that comprises, has, includes, contains the element. The terms “substantially”, “essentially”, “approximately”, “about” or any other version thereof, are defined as being close to as understood by one of ordinary skill in the art, and in one non-limiting implementation, the term is defined to be within 10%, in another implementation within 5%, in another implementation within 1% and in another implementation within 0.5%. The term “coupled” as used herein is defined as connected, although not necessarily directly and not necessarily mechanically. A device or structure that is “configured” in a certain way is configured in at least that way but may also be configured in ways that are not listed.

We claim:

1. A receiver circuitry in a storage device to provide an interface between a controller and a memory device in the storage device, the receiver circuitry comprises:
an amplifier to receive an input and produce a high gain at high and low speeds;
an equalizer to increase gain at high speeds; and
a skew balanced level down shifter to correct a duty cycle error resulting from shifting a signal across domains.

2. The receiver circuitry of claim 1, wherein the amplifier is a complimentary amplifier that receives an input of approximately 200 milli-Volts and produces the high gain in a first stage.

3. The receiver circuitry of claim 1, wherein the amplifier boosts the gain at all speeds with a complementary input folded cascade structure.

4. The receiver circuitry of claim 1, wherein complementary inputs into the amplifier provide a high input common mode range.

5. The receiver circuitry of claim 1, wherein the amplifier includes gain booster cells and devices to provide additional gain and a large output swing within an operating range.

6. The receiver circuitry of claim 1, wherein the equalizer includes one resistor and one capacitor.

7. The receiver circuitry of claim 6, wherein peak frequency in the equalizer is tunable through the capacitor.

8. The receiver circuitry of claim 6, wherein the equalizer provides a low impedance path through the resistor to improve a bandwidth of a first stage.

9. The receiver circuitry of claim 1, wherein the skew balanced level down shifter receives two signals with delay between the signals from the equalizer, wherein a first signal is an inverted signal of a second signal.

10. The receiver circuitry of claim 1, wherein the skew balanced level down shifter balances a skew, negates an impact of the skew, and level down shifts the signal to a core voltage.

11. The receiver circuitry of claim 1, wherein the skew balanced level down shifter comprises a differential level down shifter with a skew balancer and duty cycle balancers.

12. A receiver circuitry in a storage device to provide an interface between a controller and a memory device in the storage device, the receiver circuitry comprises:
an amplifier to operate in a first stage, receive an input. and produce a high gain with a complementary input folded cascade structure;
an equalizer to operate in a second stage, wherein the equalizer includes a resistor and a capacitor, and the equalizer increases the gain at high speeds; and
a level down shifter to operate in a third stage to correct a duty cycle error resulting from shifting a signal across domains.

13. The receiver circuitry of claim 12, wherein the first stage includes gain booster cells and additional devices to provide additional gain.

14. The receiver circuitry of claim 12, wherein the second stage provides a low impedance path through the resistor to improve the bandwidth of the first stage.

15. A method for interfacing between a controller and a memory device in a storage device using a receiver circuitry in the storage device, the method comprising:
receiving an input and producing a high gain with gain booster cells and a complementary input folded cascade structure in a first stage;
increasing the gain at high speeds with an equalizer in a second stage; and
correcting a duty cycle error resulting from shifting a signal across domain with a level down shifter in a third stage.
